(19) United States
(12) Patent Application Publication
(10) Pub. No.: US 2023/0409785 A1
(43) Pub. Date: Dec. 21, 2023

(54) METHOD OF MAPPING PREDICTED AIRCRAFT EXHAUST PLUMES AND ASSOCIATED SYSTEMS

(71) Applicant: The Boeing Company, Chicago, IL (US)

(72) Inventors: Mark McCabe, Larkspur, CO (US); Steven Chapel, Costa Mesa, CA (US)

(21) Appl. No.: 17/843,438

(22) Filed: Jun. 17, 2022

(51) Int. Cl. G06F 30/28; G06F 30/15; B64F 5/60

(52) U.S. Cl. CPC G06F 30/28; G06F 30/15; B64F 5/60

(57) ABSTRACT

A method and system of mapping predicted aircraft exhaust plumes within a simulated airport environment is disclosed. An exhaust plume model is generated for a simulated aircraft in a grounded position within the simulated airport environment. The exhaust plume model is generated in response to at least predicted dynamic exhaust plume data for the simulated aircraft. An airport feature map is generated for the simulated airport environment, the airport feature map comprising a digital model of the simulated airport environment. The exhaust plume model for the simulated airport in the grounded position is superimposed onto the airport feature map to display a predicted exhaust plume on a computer display. Thereafter the predicted exhaust plume is analyzed to predict exhaust plume hazard zones within the simulated airport environment.

### FIELD

This disclosure relates generally to predicting aircraft engine exhaust plumes and more particularly to mapping a predicted aircraft engine exhaust plume within a simulated airport environment.

### BACKGROUND

Exhaust plumes from aircraft engines during airport ground operations, such as engine startup, taxi, and takeoff, can create hazards. Vigilance is required to guard against economic losses or damage to other aircraft, equipment, vehicles, and structures, as well as injuries to personnel, by aircraft engine exhaust plumes. However, monitoring and predicting the potential hazards created by exhaust plumes from aircraft in a dynamic environment, such as an airport, can be difficult.

### SUMMARY

The subject matter of the present application has been developed in response to the present state of the art, and in particular, in response to the problems of and needs from conventional techniques for analyzing aircraft engine exhaust plumes that have not yet been fully solved by currently available systems. Generally, the subject matter of the present application has been developed to provide a method of mapping predicted aircraft exhaust plumes, and associated systems, that overcome at least some of the above-discussed shortcomings of prior art methods and systems.

Disclosed herein is a method of mapping predicted aircraft exhaust plumes within a simulated airport environment. The method comprises generating an exhaust plume model for a simulated aircraft in a grounded position within the simulated airport environment. The exhaust plume model is generated in response to predicted dynamic exhaust plume data for the simulated aircraft. The method also comprises generating an airport feature map for the simulated airport environment. The airport feature map comprises a digital model of the simulated airport environment. The method further comprises superimposing the exhaust plume model for the simulated aircraft in the grounded position onto the airport feature map to display a predicted exhaust plume on a computer display. Additionally, the method comprises analyzing the predicted exhaust plume to predict exhaust plume hazard zones within the simulated airport environment. The preceding subject matter of this paragraph characterizes example 1 of the present disclosure.

The exhaust plume model is further generated in response to static exhaust plume data for the simulated aircraft. The preceding subject matter of this paragraph characterizes example 2 of the present disclosure, wherein example 2 also includes the subject matter according to example 1, above.

The airport feature map comprises non-movable features, configured to be fixed relative to a ground surface of the simulated airport environment, and movable features, configured to be movable relative to the ground surface of the simulated airport environment. The preceding subject matter of this paragraph characterizes example 3 of the present disclosure, wherein example 3 also includes the subject matter according to any of examples 1-2, above.

The exhaust plume model for the simulated aircraft in the grounded position comprises a thrust level of at least one engine of the simulated aircraft. The preceding subject matter of this paragraph characterizes example 4 of the present disclosure, wherein example 4 also includes the subject matter according to any of examples 1-3, above.

The thrust level of the at least one engine of the simulated aircraft is between ground idle thrust and maximum takeoff thrust of the simulated aircraft. The preceding subject matter of this paragraph characterizes example 5 of the present disclosure, wherein example 5 also includes the subject matter according to example 4, above.

The simulated aircraft is movable about the ground surface of the simulated airport environment. The step of generating the exhaust plume model for the simulated aircraft further comprises generating the exhaust plume model for the simulated aircraft at a plurality of grounded positions within the simulated airport environment. The step of superimposing the exhaust plume model for the simulated aircraft further comprises superimposing the exhaust plume model for the simulated aircraft at each one of the plurality of grounded positions onto the airport feature map to display the predicted exhaust plume at each one of the plurality of grounded positions within the simulated airport environment on the computer display. The preceding subject matter of this paragraph characterizes example 6 of the present disclosure, wherein example 6 also includes the subject matter according to any of examples 1-5, above.

The method further comprises analyzing the predicted exhaust plume at each one of the plurality of grounded positions to predict exhaust plume hazard zones within the simulated airport environment. The method also comprises mapping a predicted path along the ground surface of the simulated airport environment. The predicted path comprises at least one of the plurality of grounded positions. Additionally, the simulated aircraft is configured to move along the predicted path while maintaining the predicted exhaust plume out of the predicted exhaust plume hazard zones. The preceding subject matter of this paragraph characterizes example 7 of the present disclosure, wherein example 7 also includes the subject matter according to example 6, above.

Generating the exhaust plume model for the simulated aircraft at the grounded position within the simulated airport environment comprises receiving at least one of: information defining a headwind at the grounded position; information defining a tailwind at the grounded position; information defining a crosswind at the grounded position; information defining an ambient temperature at the grounded position; information defining a thrust level of the aircraft at the grounded position; information defining aircraft engine configuration data of the simulated aircraft; and information defining aircraft geometry and weight data of the simulated aircraft. The preceding subject matter of this paragraph characterizes example 8 of the present disclosure, wherein example 8 also includes the subject matter according to of any examples 1-7, above.

The method further comprises generating an exhaust plume model for a secondary simulated aircraft at a secondary grounded position within the simulated airport environment. The exhaust plume model is generated in response to predicted dynamic exhaust plume data for the simulated secondary aircraft. The method also comprises superimposing the exhaust plume model for the simulated secondary aircraft at the secondary grounded position onto the airport feature map to display a predicted secondary exhaust plume within the simulated airport environment on the computer display. The method further comprises analyzing the exhaust plume model for the simulated aircraft and the exhaust plume model for the simulated secondary aircraft to determine if the exhaust plume model of the simulated aircraft merges with the exhaust plume model of the simulated secondary aircraft. The preceding subject matter of this paragraph characterizes example 9 of the present disclosure, wherein example 9 also includes the subject matter according to of any examples 1-8, above.

The method also comprises analyzing the predicted exhaust plume and the predicted secondary exhaust plume to predict exhaust plume hazard zones within the simulated airport environment. The preceding subject matter of this paragraph characterizes example 10 of the present disclosure, wherein example 10 also includes the subject matter according to example 9, above.

Further disclosure here is a system for mapping predicted aircraft exhaust plumes. The system comprises an aircraft in a grounded position within an airport environment. The system also comprises a processor communicatively coupled with the aircraft. The system further comprises non-transitory computer readable storage media storing code, the code being executable by the processor to perform operations comprising generating an exhaust plume model for a simulated aircraft in a plurality of grounded position within a simulated airport environment. The simulated aircraft is configured to simulate the movement of the aircraft and the exhaust plume model generated in response to predicted dynamic exhaust plume data for the simulated aircraft. The code is also executable to generate an airport feature map for the simulated airport environment. The airport feature map comprising a digital model of the simulated airport environment. The code is further executable to superimpose the exhaust plume model for the simulated aircraft at each one of the plurality of grounded positions onto the airport feature map to display a predicted exhaust plume at each one of the plurality of grounded positions on a computer display. Additionally, the code is executable to analyze the predicted exhaust plume at each one of the plurality of grounded positions to predict exhaust plume hazard zones within the simulated airport environment. The code is further executable to map a predicted path along the ground surface of the simulated airport environment. The predicted path comprises at least one of the plurality of grounded positions and the simulated aircraft is configured to move along the predicted path while maintaining the predicted exhaust plume out of the predict exhaust plume hazard zones. The aircraft of the system is configured to move along a path in response to the predicted path within the airport environment. The preceding subject matter of this paragraph characterizes example 11 of the present disclosure.

The exhaust plume model is further generated in response to static exhaust plume data for the simulated aircraft. The preceding subject matter of this paragraph characterizes example 12 of the present disclosure, wherein example 12 also includes the subject matter according to example 11, above.

The processor is remote from the aircraft. The preceding subject matter of this paragraph characterizes example 12 of the present disclosure, wherein example 12 also includes the subject matter according to any of examples 11-12, above.

Alternatively, the processor is onboard the aircraft. The preceding subject matter of this paragraph characterizes example 14 of the present disclosure, wherein example 14 also includes the subject matter according to any of examples 11-12, above.

The predicted path is mapped in real-time as the aircraft is moved along the path in response to the predicted path within the airport environment. The preceding subject matter of this paragraph characterizes example 15 of the present disclosure, wherein example 15 also includes the subject matter according to any of examples 11-14, above.

The step of generating the exhaust plume model for the simulated aircraft at the plurality of grounded positions within the simulated airport environment comprises receiving at least one of: information defining a headwind at the grounded position; information defining a tailwind at the grounded position; information defining a crosswind at the grounded position; information defining an ambient temperature at the grounded position; information defining a thrust level of the aircraft at the grounded position; information defining aircraft engine configuration data of the simulated aircraft; and information defining aircraft geometry and weight data of the simulated aircraft. The preceding subject matter of this paragraph characterizes example 16 of the present disclosure, wherein example 16 also includes the subject matter according to any of examples 11-15, above.

Additionally, disclosed herein is a program product for mapping predicted aircraft exhaust plumes within a simulated airport environment. The program product comprising a non-transitory computer readable storage medium storing code, the code being configured to be executable by a processor to perform operations comprising generating an exhaust plume model for a simulated aircraft in a grounded position within the simulated airport environment. The exhaust plume model is generated in response to predicted dynamic exhaust plume data for the simulated aircraft. The code is also configured to be executable to generate an airport feature map for the simulated airport environment, the airport feature map comprising a digital model of the simulated airport environment. The code is further configured to be executable to superimpose the exhaust plume model for the simulated aircraft in the grounded position onto the airport feature map to display a predicted exhaust plume on a computer display. Additionally, the code is configured to be executable to analyze the predicted exhaust plume to predict exhaust plume hazard zones. The preceding subject matter of this paragraph characterizes example 17 of the present disclosure.

The exhaust plume model is further generated in response to static exhaust plume data for the simulated aircraft. The preceding subject matter of this paragraph characterizes example 18 of the present disclosure, wherein example 18 also includes the subject matter according to example 17, above.

The airport feature map comprises non-movable features, configured to be fixed relative to a ground surface of the simulated airport environment, and movable features, configured to be movable relative to the ground surface of the simulated airport environment. The preceding subject matter of this paragraph characterizes example 19 of the present disclosure, wherein example 19 also includes the subject matter according to any of examples 17-18, above.

The code is further configured to generate the exhaust plume model for the simulated aircraft at a plurality of grounded positions within the simulated airport environment. The code is also configured to superimpose the exhaust plume model for the simulated aircraft for the plurality of grounded positions onto the airport feature map to display the predicted exhaust plume at each one of the plurality of grounded positions within the simulated airport environment on the computer display. The preceding subject matter of this paragraph characterizes example 20 of the present disclosure, wherein example 20 also includes the subject matter according to any of examples 17-19, above.

The described features, structures, advantages, and/or characteristics of the subject matter of the present disclosure may be combined in any suitable manner in one or more examples, including embodiments and/or implementations. In the following description, numerous specific details are provided to impart a thorough understanding of examples of the subject matter of the present disclosure. One skilled in the relevant art will recognize that the subject matter of the present disclosure may be practiced without one or more of the specific features, details, components, materials, and/or methods of a particular example, embodiment, or implementation. In other instances, additional features and advantages may be recognized in certain examples, embodiments, and/or implementations that may not be present in all examples, embodiments, or implementations. Further, in some instances, well-known structures, materials, or operations are not shown or described in detail to avoid obscuring aspects of the subject matter of the present disclosure. The features and advantages of the subject matter of the present disclosure will become more fully apparent from the following description and appended claims, or may be learned by the practice of the subject matter as set forth hereinafter.

### BRIEF DESCRIPTION OF THE DRAWINGS

In order that the advantages of the subject matter may be more readily understood, a more particular description of the subject matter briefly described above will be rendered by reference to specific examples that are illustrated in the appended drawings. Understanding that these drawings depict only typical examples of the subject matter, they are not therefore to be considered to be limiting of its scope. The subject matter will be described and explained with additional specificity and detail through the use of the drawings, in which:

FIG. 1 is a schematic block diagram illustrating a system for mapping predicted aircraft exhaust plumes, according to one or more examples of the present disclosure;

FIG. 2 is a schematic block diagram illustrating a processor circuit for mapping predicted aircraft exhaust plumes, according to one or more examples of the present disclosure;

FIG. 3 is a schematic top view of a simulated airport environment with a simulated aircraft in a grounded position, according to one or more examples of the present disclosure;

FIG. 4 is a schematic top view of a two-engined simulated aircraft with a representative progression of predicted exhaust plumes, according to one or more examples of the present disclosure;

FIG. 5 is a schematic top view of a four-engined simulated aircraft with a representative progression of predicted exhaust plumes, according to one or more examples of the present disclosure;

FIG. 6 is a schematic top view of a four-engined simulated aircraft with a representative progression of predicted exhaust plumes, the predicted exhaust plume altered by a crosswind input, according to one or more examples of the present disclosure;

FIG. 7 is a schematic top view of a simulated aircraft and a simulated secondary aircraft each with a predicted exhaust plume, according to one or more examples of the present disclosure;

FIG. 8 is a schematic top view of a simulated aircraft moving along a predicted path, according to one or more examples of the present disclosure;

FIG. 9 is a schematic top view of a system for mapping predicted aircraft exhaust plumes within a simulated airport environment; and

FIG. 10 is a schematic flow chart diagram of a method for mapping predicting aircraft exhaust plumes within a simulated airport environment, according to one or more examples of the present disclosure.

### DETAILED DESCRIPTION

As will be appreciated by one skilled in the art, aspects of the embodiments may be embodied as a system, method or program product. Accordingly, embodiments may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, embodiments may take the form of a program product embodied in one or more computer readable storage devices storing machine readable code, computer readable code, and/or program code, referred hereafter as code. The storage devices, in some embodiments, are tangible, non-transitory, and/or non-transmission.

Reference throughout this specification to “one example,” “an example,” or similar language means that a particular feature, structure, or characteristic described in connection with the example is included in at least one example of the subject matter of the present disclosure. Appearances of the phrases “in one example,” “in an example,” and similar language throughout this specification may, but do not necessarily, all refer to the same example. Similarly, the use of the term “implementation” means an implementation having a particular feature, structure, or characteristic described in connection with one or more examples of the subject matter of the present disclosure, however, absent an express correlation to indicate otherwise, an implementation may be associated with one or more examples.

Accurate prediction of hazards within airport environments help to ensure the safe and economical ground operations of aircraft within the airport environment. Conventional models for predicting the characteristics of an exhaust plume from an aircraft are limited to static environments. Such models are not sufficiently detailed to account for the variety of routine aircraft ground operations that aircraft experience within a dynamic environment, such as an airport environment. Additionally, existing static models cannot be readily adapted to assess hazards posed by the exhaust plume of new aircraft types and configurations. Therefore, changes to aircraft parameters, such as the horizontal distance changes between engines or increased weight of aircraft, cannot be accurately predicted by the conventional tools. Accordingly, currently available tools can lead to inaccurate and incomplete prediction of the hazards posed by an aircraft engine exhaust plume, particularly when operated in a dynamic environment.

Disclosed herein is a method, system, and program product that improve the prediction of aircraft engine exhaust plumes. More specifically, the method, system, and program product disclosed herein increase the accuracy of predicted aircraft engine exhaust plumes within a simulated airport environment during a range of ground operations. Accurate predictions of aircraft engine exhaust plumes can be used to predict hazard zones within an airport environment. The accurate prediction of hazard zones helps ensure that the ground operations within the airport environment are performed in a safe and economical manner. Accordingly, accurate predictions of hazard zones can contribute to optimized planning within the airport environment, such as planning traffic patterns for aircraft and other vehicles, specifying safe distances from aircraft for personnel and equipment, etc. As used herein, a hazard zone is a zone where one or more characteristics of an aircraft exhaust plume exceeds a specified value. For example, the specified value may be a plume speed greater than a defined speed, such as a speed greater than 35 miles per hour, a widely used threshold within the aircraft industry. In other examples, the hazard zone may be based on exceeding a specified air temperature threshold or a dynamic pressure threshold. In other examples, the hazard zone may be based on multiple characteristics of the aircraft exhaust plume, such as a combination of the plume speed and air temperature. Accordingly, in some examples, a user can define the specified characteristic or multiple characteristics that, once exceeded, define the hazard zone. In other examples, the characteristics defining the hazard zone can be based on industry standard or regulations.

By pairing a highly detailed airport feature map with the predicted aircraft exhaust plume model, the limitations of conventional tools and models can be overcome. Conventional tools, using a static exhaust plume model, are primarily collected using an aircraft on a test stand under static conditions. In some cases, the static exhaust plume model is generalized data and not collected using an actual aircraft configuration. Unlike the static exhaust plume models, which lack sufficient detail to analyze routine aircraft operations, such as single-engine taxi, varying engine thrust during taxi, effects of wind, aircraft movement about the airport environment, etc., dynamic exhaust plume modeling provides ample flexibility and controls to model a full range of engine thrust settings and other changing conditions demanded by routine ground movement. The ability to map predicted aircraft exhaust plume within a simulated airport environment can be useful for airlines and airports to ensure safe and economical ground operations within the airport environment. Additionally, future airport design and planning may also be improved.

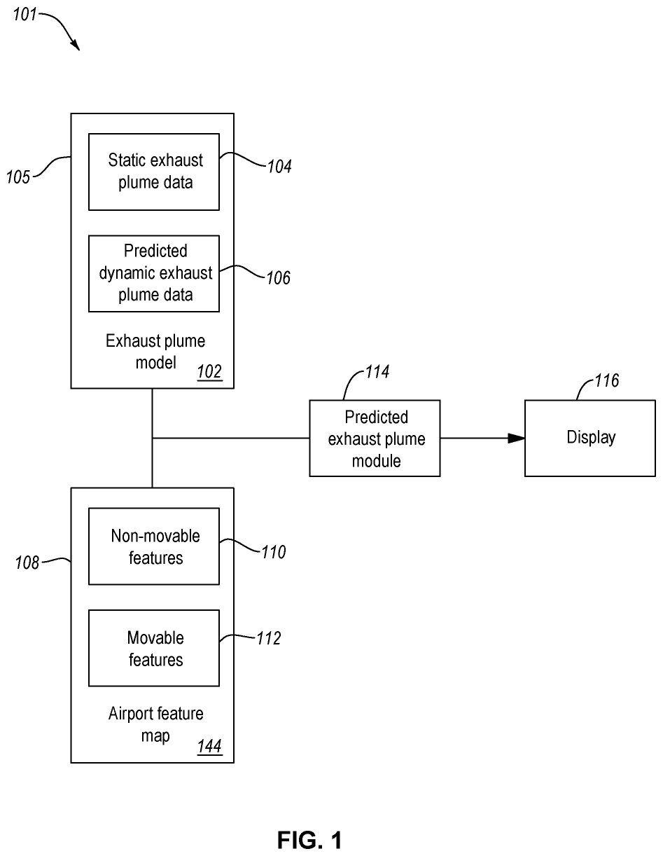

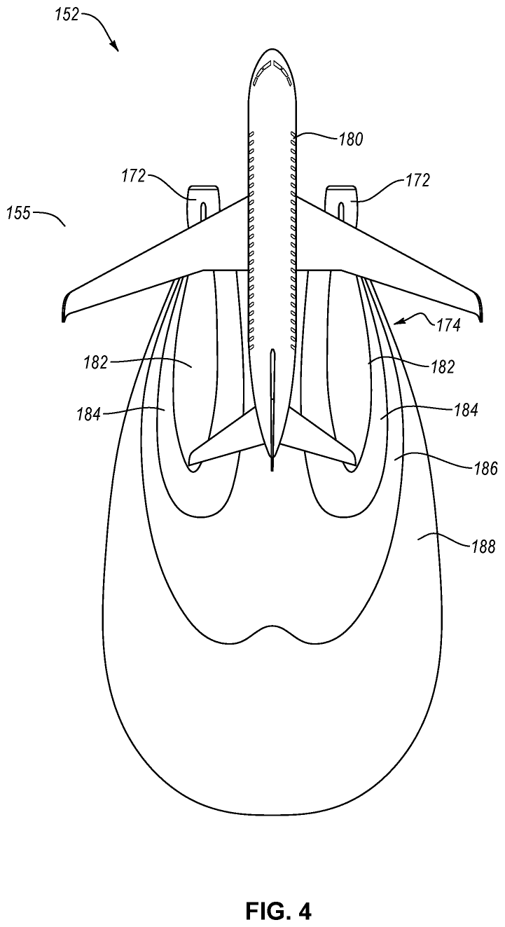

Referring to FIG. 1, a block diagram of a system 101 of mapping a predicted aircraft exhaust plume within a simulated airport environment is shown. The system 101 includes an exhaust module 105 that is configured to generate an exhaust plume model 102 for a simulated aircraft in a grounded position within the simulated airport environment. In one example, the exhaust module 105 is configured to generate the exhaust plume model 102 in response to predicted dynamic exhaust plume data 106. The predicted dynamic exhaust plume data 106 may be obtained using semi-empirical prediction models, such as computational fluid dynamic predictions of the engine plume field geometry. The predicted dynamic exhaust plume data 106 provides provisions for at least one of the following: information defining a headwind at the grounded position, information defining a tailwind at the grounded position, information defining a crosswind at the grounded position, information defining an ambient temperature at the grounded position, information defining a thrust level of the aircraft at the grounded position, information defining aircraft engine configuration data of the simulated aircraft, and information defining aircraft geometry and weight data of the simulated aircraft. For example, the predicted dynamic exhaust plume data 106 can include data regarding various thrust levels of the aircraft at the grounded position. In other words, the exhaust plume model 102 accounts for the predicted exhaust plume at each of the various thrust levels (see, e.g., FIGS. 4-6). The predicted dynamic exhaust plume data 106 can be calculated using any of various semi-empirical prediction models (i.e., a physics-based model). In some examples, an actuator-disc model is used to generate the predicted dynamic exhaust plume data 106.

In some examples, static exhaust plume data 104 can be used to supplement the predicted dynamic exhaust plume data 106. As used herein static exhaust plume data 104 refers to measured exhaust plume data obtained through static testing on physical aircraft. When static exhaust plume data 104 is available for an aircraft that corresponds with the simulated aircraft, the static exhaust plume data 104 and the predicted dynamic exhaust plume data 106 can be combined by the exhaust module 105 to generate the exhaust plume model 102. Static exhaust plume data 104 for an aircraft is considered to correspond with the simulated aircraft if one or more primary characteristics of the aircraft are equivalent with one or more primary characteristics of the simulated aircraft such as engine configuration, aircraft weight, overall aircraft shape, etc. In some cases, static exhaust plume data 104 is available from aircraft manufactures for specific aircraft that correspond with the simulated aircraft.

A map module 108 is configured to generate an airport feature map 144 for the simulated airport environment. The airport feature map 144 is a digital model of the simulated airport environment. For example, the simulated airport environment may be a digital representation based on a factual airport environment or a fictitious airport environment, such as a proposed airport environment. In one example, the map module 108 is configured to generate the airport feature map 144 including all non-movable features 110, that is, features that are fixed relative to a ground surface of the simulated airport environment. Non-movable features 110 include, but are not limited to, runways, taxiways, and airport structures such as terminals, hangars, control towers, fire stations, etc. In other examples, the map module 108 is configured to additionally generate the airport feature map 144 to include movable features 112, that is, features that are configured to be movable relative to the ground surface of the simulated airport environment. Movable features 112 may include, but are not limited to aircraft, service vehicles, personnel, airport equipment (e.g., jet bridge), construction areas, etc.

The predicted exhaust plume module 114 is configured to superimpose the exhaust plume model 102 for the simulated aircraft in the grounded position generated by the exhaust module 105 onto the airport feature map 144 generated by the map module 108. Accordingly, a predicted exhaust plume is displayed on the airport feature map and is viewable via a computer display 116, such as a computer monitor.

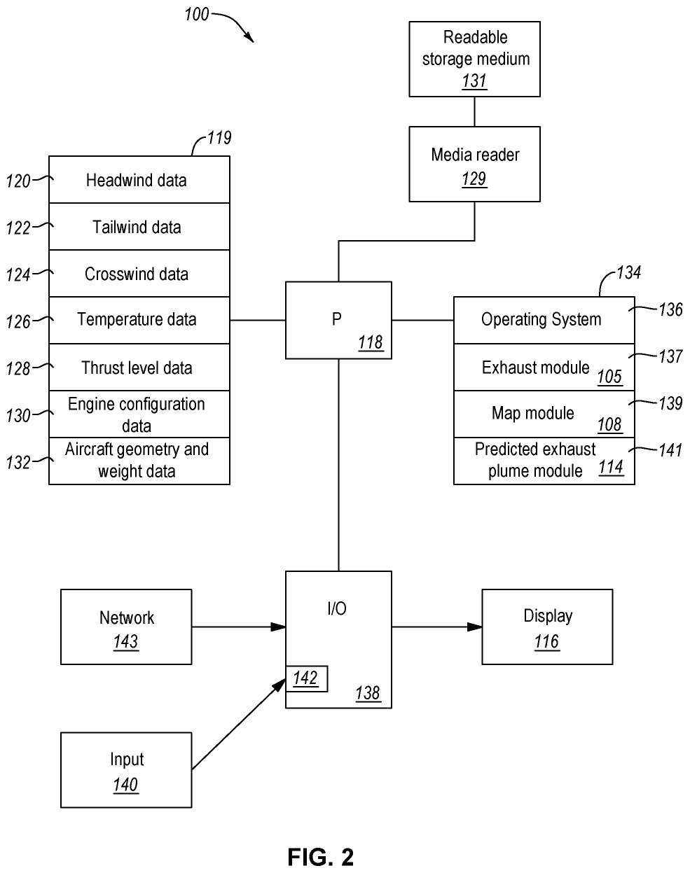

Referring to FIG. 2, a system 100 including a processor circuit for implementing the system 101 of FIG. 1 is shown. A system 100 includes a processor 118, a program memory 134, a variable memory 119, a media reader 129, and an input/output port (I/O) 138, all of which are in communication with the processor 118.

Program codes for directing the processor 118 to carry out various functions are stored in the program memory 134, which may be implemented as a random access memory (RAM), flash memory, and/or a hard disk drive (HDD), for example. The program memory 134 includes a first block of program codes 136 for directing the processor 118 to perform operating system functions, which in one example, may be a version of the Microsoft Windows operating system. The program memory 134 includes a second block of program codes 137 for directing the processor 118 to perform exhaust plume model 102 generation, via the exhaust module 105. The program memory 134 additionally includes a third block of program codes 139 for directing the processor 118 to perform airport feature map 144 generation, via the map module 108, and a fourth block of program codes 141 for directing the processor 118 to superimpose the exhaust plume model 102 within the airport feature map 144, via the predicted exhaust plume module 114. The actual code to implement each block may be written in any suitable program language, such as C++ or other program language supported by the processor 118.

The media reader 129 facilitates loading program codes into the program memory 134 from a computer readable medium 131, for examples, a computer readable signal, which may be received over a network such as the internet, for example. The I/O 138 includes a user interface 142, configured to allow a user to interface with the processor 118 and an input 140 for receiving user input, such as a keyboard and a pointing device. A network 143, such as an intranet or the internet, is in communication with the I/O 138 via a wireless or wired network. The I/O 138 further includes an output for producing output data, such as a display 116.

The variable memory 119 includes a plurality of storage locations including a memory store for storing headwind data 120, a memory store for storing tailwind data 122, a memory store for storing crosswind data 124, a memory store for storing temperature data 126, a memory store for storing thrust level data 128, a memory store for storing engine configuration data 130 and a memory store for storing aircraft geometry and weight data 132. The variable memory 119 may be implemented as a RAM, flash memory, or a hard drive, for example. The variable memory 119 permits a user, using the processor 118, to input data specific to the conditions within the simulated airport environment and the simulated aircraft, such as the thrust level of the aircraft. A user, using the system 100, can input values into the variable memory 119 to adjust the results of a generated exhaust plume model 102.

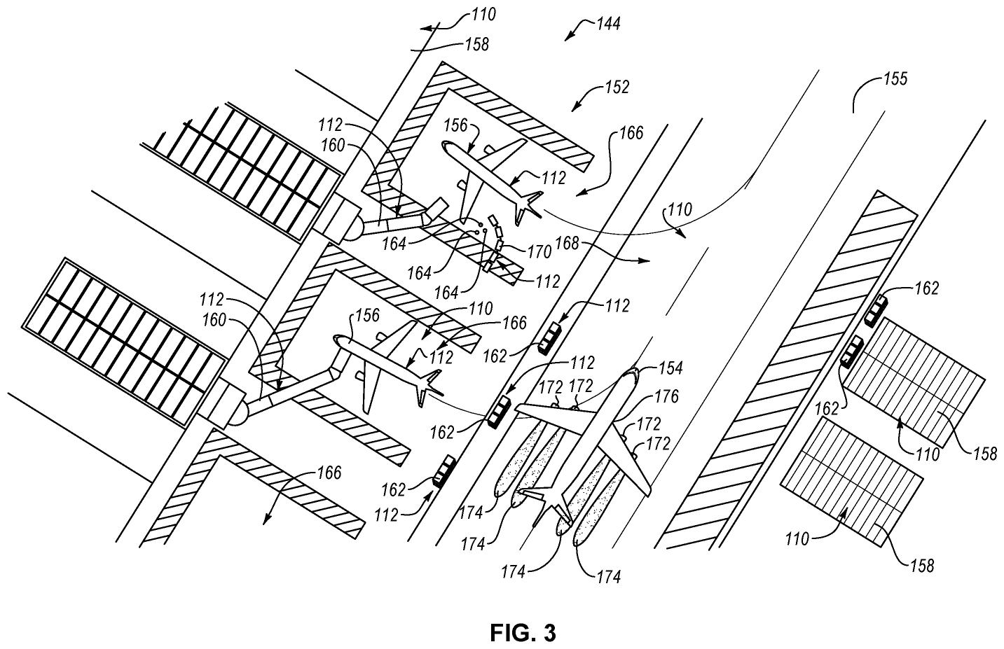

An airport feature map 144, according to one example, is shown in FIG. 3. The airport feature map 144 is a digital model of a simulated airport environment 152. The airport feature map 144 provides features and details that improve the identification of exhaust plume hazard zones. The airport feature map 144, as shown, includes a plurality of non-movable features 110 and movable features 112. The airport feature map 144 includes a ground surface 155 to which the non-movable features 110 are fixed relative to the ground surface 155. Non-movable features 110 include airport structures 158, which may include airport terminals, parking garages, airport hangers, control towers, fire stations, etc. Non-movable features 110 also include runways, taxiways 168, aprons 166, hot spots (i.e., airport ground surface areas with frequent aircraft and support vehicle operations), runway and intermediate holding position areas, and other areas along the ground surface 155 where the simulated aircraft 154 may move.

Movable features 112, of the airport feature map 144, include features that are configured to be movable relative to the ground surface 155. Movable features 112 include jet bridges 160, personnel 164 or other individuals within the simulated airport environment 152, service vehicles 162, equipment 170, secondary aircraft 156, etc. The airport feature map 144 may include movable features 112 in locations where the movable features 112 are most likely to be located, such as approximate to aprons 166 or taxiways 168. In other words, the airport feature map 144 may include movable features in locations where the movable features 112 would be expected to be located. By identifying the expected location of the movable features 112 it is possible to identify a predicted exhaust plume hazard zones where heightened caution and vigilance is exercised, regardless of what specify type of movable feature 112 is currently located in the location. Additionally, an area may be determined to be a predicted exhaust plume hazard zone based on the possibility of movable features 112 being located in a specific area regardless of whether movable feature 112 are positioned in the specific area at the immediate time. In some examples, airports may use the data regarding predicted exhaust plume hazard zones to post signage, within or near the predicted exhaust plume hazard zones, warning others of any potential risks from exhaust plumes in the area.

The exhaust plume model for a simulated aircraft 154 is superimposed on the airport feature map 144. Accordingly, the simulated aircraft 154 is shown within the airport feature map 144 with a predicted exhaust plume 174 and in at least one grounded position 176. Using the exhaust module 105 (see, e.g., FIG. 1), a user can adjust information regarding characteristics of the aircraft, wind, etc., to visualize the changes to the predicted exhaust plume 174. In some examples, the airport feature map 144 can restrict the areas where the simulated aircraft 154 can be in a grounded position to areas in which the simulated aircraft 154 could reasonably occupy. Such restrictions include runways, taxiways, or ramp areas that are prohibited to certain aircraft due to a large wingspan or weight limitations. The location of the predicted exhaust plume 174 of the simulated aircraft 154 is displayed relative to the non-movable features 110 and movable features 112.

The simulated aircraft 154 is movable about the ground surface 155 of the simulated airport environment 152. Accordingly, the exhaust plume model for the simulated aircraft 154 can be generated to show the simulated aircraft 154 at a plurality of grounded positions 176 within the simulated airport environment 152. In other words, as the simulated aircraft 154 moves within the simulated airport environment 152 the exhaust plume model can be used to predict the predicted exhaust plume 174 during the movement. In some examples, the movement of the simulated aircraft 154 through the simulated airport environment 152 can be viewed as an animation within the airport feature map 144.

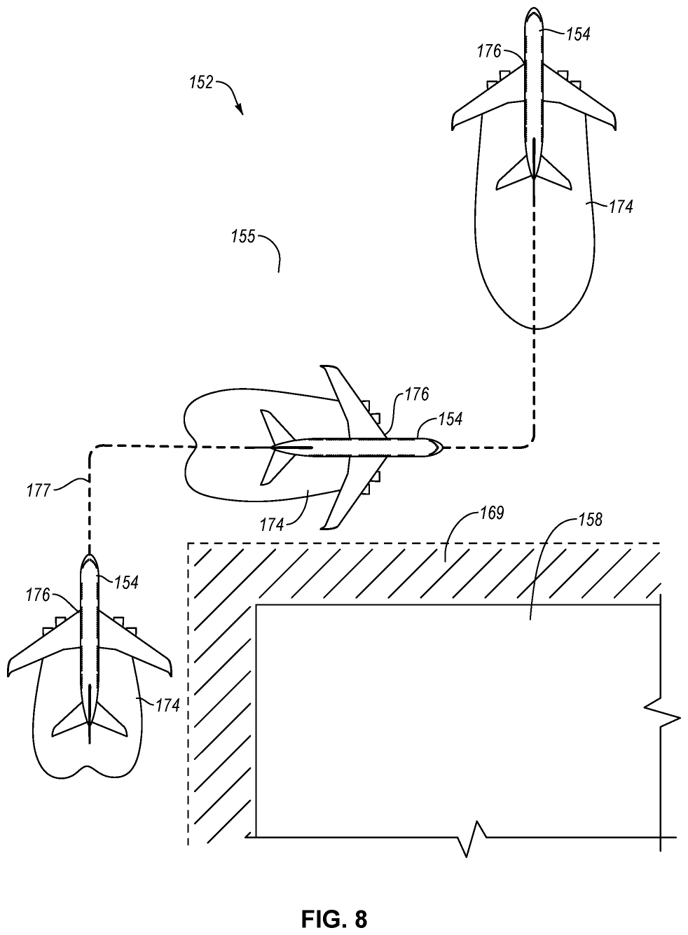

The predicted exhaust plumes 174, at each one of the plurality of grounded positions 176 of the simulated aircraft 154, can be analyzed to determine a predicted path 177 in which the simulated aircraft 154 is configured to move along. As shown in FIG. 8, the simulated aircraft 154 is shown in various grounded positions 176 along the predicted path 177. While moving along the predicted path 177, the predicted exhaust plume 174 of the simulated aircraft 154 is maintained out of a predicted exhaust plume hazard zone. In other words, the predicted path 177 is limited to areas where the simulated aircraft 154 can move without creating a potentially hazardous condition and the predicted exhaust plume 174 does not encroach on any predicted exhaust plume hazard zones 169.

Referring to FIGS. 4-7, some examples of predicted exhaust plumes 174, generated by the exhaust module 105 for different configurations of simulated aircraft, are shown. The effect that interaction of an individual simulated aircraft has on the characteristics of the overall predicted exhaust plume depends on the particular aircraft configuration. As shown in FIG. 4, the simulated aircraft is a two-engine aircraft 180 (i.e., twinjet), and includes an engine 172 mounted beneath each wing. The configuration of the two-engine aircraft 180 could be varied to have the engines 172 mounted above or within each wing, mounted on each side of the rear fuselage, or other configurations. At a low thrust level, such as idle thrust, assuming the engines 172 of the two-engine aircraft 180 are mounted far enough apart, there may be little interaction between the predicted exhaust plumes from each engine, such as exhaust plumes 182. Accordingly, each one of the predicted exhaust plumes 182 will decay independent of each other. In this case, the downstream extent of the predicted exhaust plume will be determined by the thrust of the individual engines rather than the total thrust. As the thrust level is increased the predicted exhaust plumes of each engine 172 will lengthen, such as predicted exhaust plumes 184. At some thrust level, the predicted exhaust plumes will begin to merge, such as shown by predicted exhaust plumes 186. Eventually, the individual predicted exhaust plumes will start to behave as a single predicted exhaust plume 188, such as when the simulated aircraft 180 is at a maximum takeoff thrust. The predicted exhaust plumes 182, 184, 186, and 188 are not drawn to scale, in reality the predicted exhaust plumes may extend hundreds to thousands of feet from the aft of the engines 172.

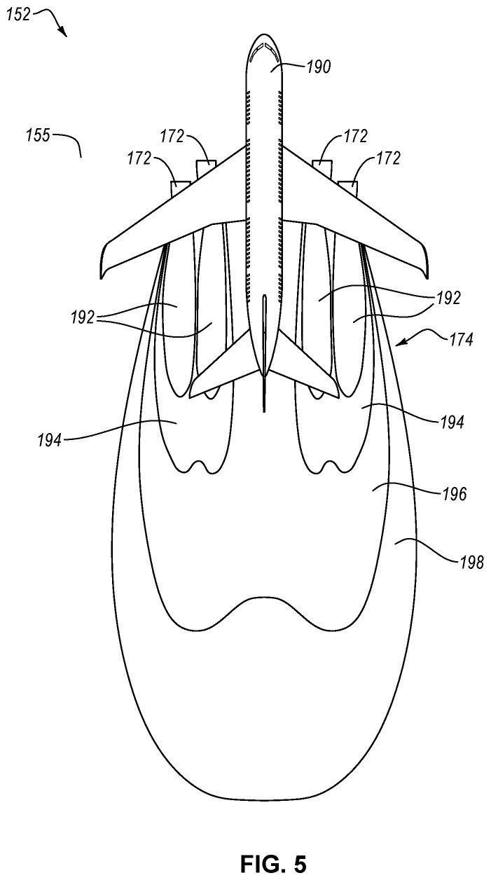

The simulated aircraft in FIG. 5 is a four-engine aircraft 190 with two engines 172 mounted beneath each wing. At a low thrust level, there may be little interaction between the predicted exhaust plumes from each engine 172, such as exhaust plumes 192. As the thrust level is increased the predicted exhaust plumes of each engine 172 will lengthen and start to merge with the predicted exhaust plume of the same-sided engine, such as predicted exhaust plumes 194. At some thrust level, the predicted exhaust plumes on one side of the aircraft 190 will merge with the predicted exhaust plumes on the other side of the aircraft 190, such as shown by predicted exhaust plumes 196. Eventually the predicted exhaust plumes from all four engines will start to behave as a single predicted exhaust plume 198, such as when the simulated aircraft 190 is at a maximum takeoff thrust. In some cases, when engines are tightly clustered together, such as three engines in close proximity to each other, the plumes will interact strongly a short distance behind the aircraft and, except at very low power settings, the predicted exhaust plumes will behave as if it were generated by a single engine.

Alternatively, in some cases, only some engines on the aircraft will be in use, such as one engine 172 on the simulated aircraft 190. Unlike static exhaust plume models, which cannot analyze single-engine use, the exhaust module 105 can use predicted dynamic exhaust plume data 106 to predict the predicted exhaust plume 174 of the simulated aircraft 190, using a single-engine.

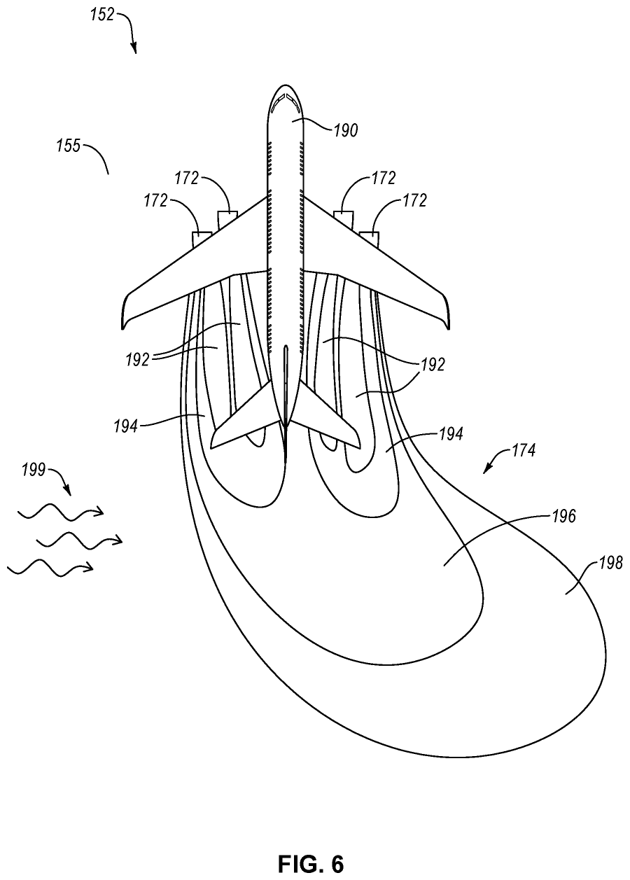

Additionally, in some cases, wind can affect the characteristics of the predicted exhaust plume 174, such as the direction, width, and length. As shown in FIG. 6, a crosswind 199 is moving toward a side of the simulated aircraft 190. The crosswind 199, together with any headwinds or tailwinds, will alter at least one characteristic of the predicted exhaust plumes. As the headwind, crosswind, and tailwind will alter the characteristics of the predicted exhaust plume 174, in some cases, they will change the size of the predicted exhaust plume hazard zone. Again, the exhaust module 105 can use predicted dynamic exhaust plume data 106 to predict the predicted exhaust plume 174 of the simulated aircraft 190 by the addition of the information regarding the crosswind 199 to the data set.

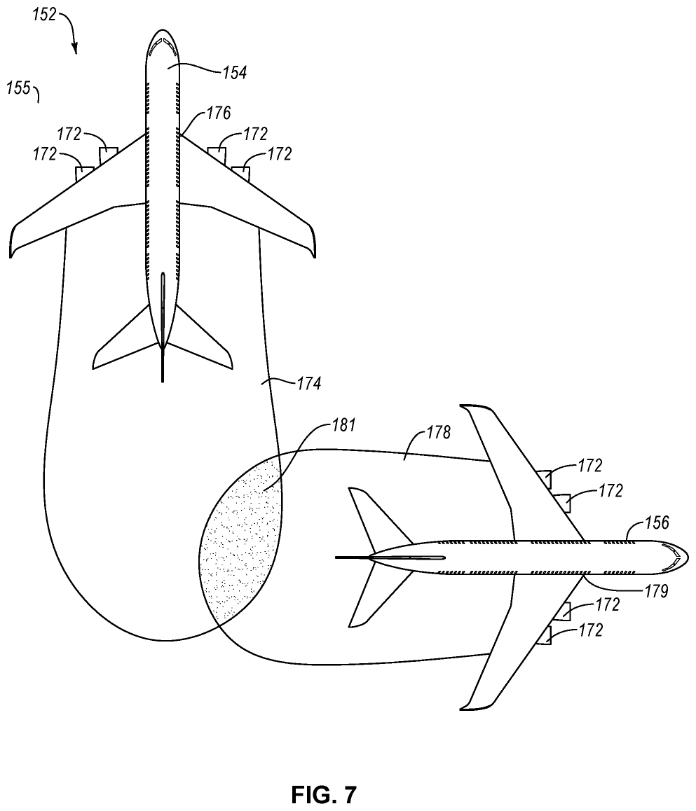

The exhaust module 105 can also be used to predict the merging of exhaust plume from multiple aircraft. As shown in FIG. 7, the simulated aircraft 154, in a grounded position 176, has a predicted exhaust plume 174. A secondary simulated aircraft 156, in a secondary grounded position 179, has a predicted exhaust plume 178 that overlaps with the predicted exhaust plume 174 of the simulated aircraft 154, such that a merged exhaust zone 181 is created. The merger of multiple exhaust plume may cause the merged exhaust zone 181 to have different characteristics than the individual, non-merged exhaust plume, such as a larger exhaust plume. Accordingly, the merged predicted exhaust plume data is analyzed to predict exhaust plume hazard zones based on the merged exhaust zone 181.

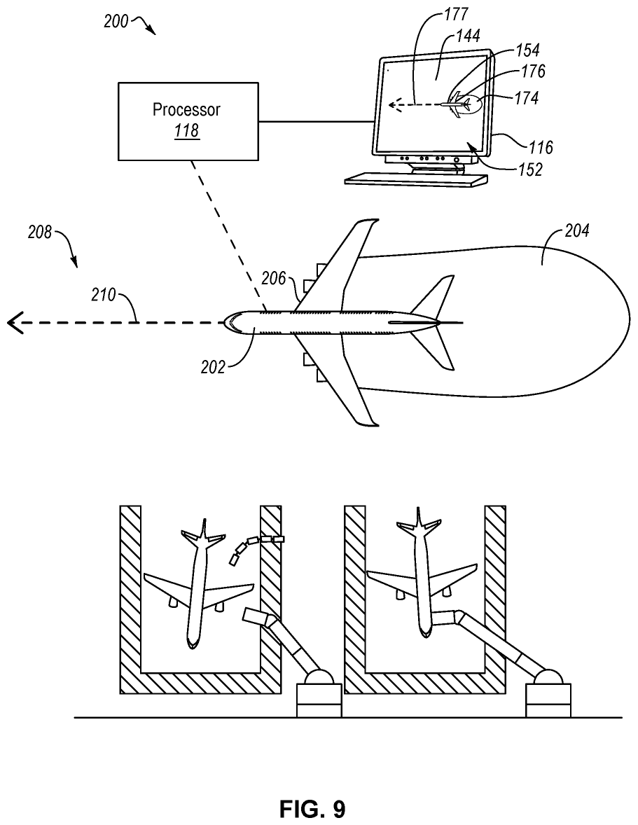

A system 200 for mapping predicted aircraft exhaust plume is shown in FIG. 9. The system 200 includes an aircraft 202 in a grounded position 206 within an airport environment 208. The processor 118 (see, e.g., FIG. 2) is communicatively coupled with the aircraft 202. In one example, the processor 118 is remote from the aircraft 202, such as in a control tower. In other examples, the processor 118 is onboard the aircraft 202. In some examples, a pilot or other operator can interact with the processor 118 while onboard the aircraft 202. The processor 118 is configured to execute non-transitory computer readable storage media storing code to perform the mapping operations of a simulated aircraft 154. The processor 118 generates the exhaust plume model for the simulated aircraft 154 within a simulated airport environment 152 in a plurality of grounded positions 176. The simulated aircraft 154 corresponds with the aircraft 202 and is configured to simulate the movement of the aircraft 202. That is, the simulated aircraft 154 is based on the aircraft 202, such that the simulated aircraft 154 is a representative model of the aircraft 202. The movement of the simulated aircraft 154 is therefore modeled by the system 200 to find a path 210 on a grounded surface of the airport environment 208 along which the aircraft 202 can safely move.

The exhaust plume model is generated in response to predicted dynamic exhaust plume data for the simulated aircraft 154. In some examples, the exhaust plume model also considers static exhaust plume data 104, the data being based on the aircraft 202. The processor 118 generates an airport feature map 144 for the simulated airport environment 152. The exhaust plume model for the simulated aircraft 154 at each one of the plurality of grounded positions 176 is superimposed onto the airport feature map 144 to display a predicted exhaust plume 174 at each one of the plurality of grounded positions 176 on a computer display 116. The predicted exhaust plume 174 is analyzed to predict exhaust plume hazard zones within the simulated airport environment 152. A predicted path 177 is mapped within the simulated airport environment 152 that includes at least one of the plurality of grounded positions 176. The simulated aircraft 154 is configure to move along the predicted path 177 while maintaining the predicted exhaust plume 174 out of the predicted exhaust plume hazard zones.

The aircraft 202 is configured to move along the path 210, corresponding to the predicted path 177 in the simulated airport environment 152. In other words, the predicted path 177 in the simulated airport environment 152 is a representative model of the path 210 in the actual airport environment 208. In some cases, the predicted path 177 is mapped in real-time as the aircraft 202 moves along the path 210, in response to the predicted path 177, within the airport environment 208. That is, as the predicted path 177 is determined by the system 200, the aircraft 202 is configured to immediately move along the path 210. In other examples, the predicted path 177 is determined prior to the aircraft 202 moving along the path 210.

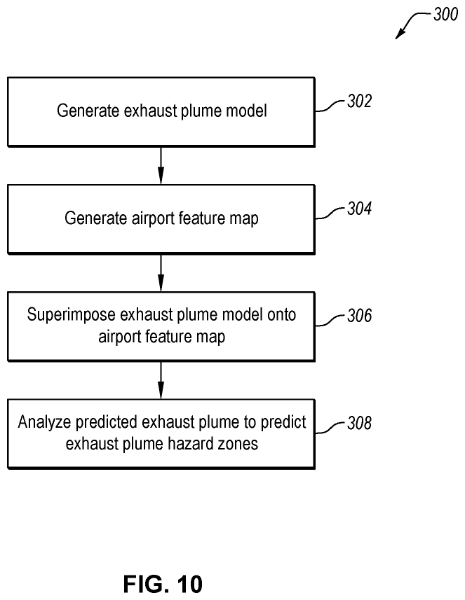

Referring to FIG. 10, according to some examples, a method 300 of mapping predicted aircraft exhaust plumes is shown. The method includes (block 302) the step of generating an exhaust plume model 102 for a simulated aircraft 154 in a grounded position 176 within a simulated airport environment 152. The exhaust plume model 102 is generated in response to predicted dynamic exhaust plume data 106 for the simulated aircraft 154. Predicted dynamic exhaust plume data 106 allows the model to accurately predict the exhaust plume during a range of ground operations. In some examples, the exhaust plume model 102 is additionally generated in response to static exhaust plume data 104 for the simulated aircraft 154.

The method also includes (block 304) the step of generating an airport feature map 144 for the simulated airport environment 152. The airport feature map 144 is a digital model of the simulated airport environment 152. The airport feature map 144 includes non-movable features 110 that are configured to be fixed relative to a ground surface 155 of the simulated airport environment 152. Additionally, in some examples, the airport feature map 144 also includes movable features 112 configured to be movable relative to the ground surface 155 of the simulated airport environment 152. The method further includes (block 306) superimposing the exhaust plume model 102 for the simulated aircraft 154 in the grounded position 176 onto the airport feature map 144. Accordingly, the predicted exhaust plume 174 is displayed on a computer display 116. Additionally, the method includes (block 308) analyzing the predicted exhaust plume 174 to predict exhaust plume hazard zones within the simulated airport environment 152. The accurate prediction of the exhaust plume hazard zones helps ensure that the ground operations within the simulated airport environment 152 are performed in a safe and economical manner.

In the above description, many of the functional units described in this specification have been labeled as modules, in order to more particularly emphasize their implementation independence. For example, a module may be implemented as a hardware circuit comprising custom very large scale integrated (“VLSI”) circuits or gate arrays, off-the-shelf semiconductors such as logic chips, transistors, or other discrete components. A module may also be implemented in programmable hardware devices such as a field programmable gate array (“FPGA”), programmable array logic, programmable logic devices or the like.

Modules may also be implemented in code and/or software for execution by various types of processors. An identified module of code may, for instance, comprise one or more physical or logical blocks of executable code which may, for instance, be organized as an object, procedure, or function. Nevertheless, the executables of an identified module need not be physically located together, but may comprise disparate instructions stored in different locations which, when joined logically together, comprise the module and achieve the stated purpose for the module.

Indeed, a module of code may be a single instruction, or many instructions, and may even be distributed over several different code segments, among different programs, and across several memory devices. Similarly, operational data may be identified and illustrated herein within modules, and may be embodied in any suitable form and organized within any suitable type of data structure. The operational data may be collected as a single data set, or may be distributed over different locations including over different computer readable storage devices. Where a module or portions of a module are implemented in software, the software portions are stored on one or more computer readable storage devices.

In the above description, certain terms may be used such as “up,” “down,” “upper,” “lower,” “horizontal,” “vertical,” “left,” “right,” “over,” “under” and the like. These terms are used, where applicable, to provide some clarity of description when dealing with relative relationships. But, these terms are not intended to imply absolute relationships, positions, and/or orientations. For example, with respect to an object, an “upper” surface can become a “lower” surface simply by turning the object over. Nevertheless, it is still the same object. Further, the terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise. Further, the term “plurality” can be defined as “at least two.”

Additionally, instances in this specification where one element is “coupled” to another element can include direct and indirect coupling. Direct coupling can be defined as one element coupled to and in some contact with another element. Indirect coupling can be defined as coupling between two elements not in direct contact with each other, but having one or more additional elements between the coupled elements. Further, as used herein, securing one element to another element can include direct securing and indirect securing. Additionally, as used herein, “adjacent” does not necessarily denote contact. For example, one element can be adjacent another element without being in contact with that element.

As used herein, the phrase “at least one of”, when used with a list of items, means different combinations of one or more of the listed items may be used and only one of the items in the list may be needed. The item may be a particular object, thing, or category. In other words, “at least one of” means any combination of items or number of items may be used from the list, but not all of the items in the list may be required. For example, “at least one of item A, item B, and item C” may mean item A; item A and item B; item B; item A, item B, and item C; or item B and item C. In some cases, “at least one of item A, item B, and item C” may mean, for example, without limitation, two of item A, one of item B, and ten of item C; four of item B and seven of item C; or some other suitable combination.

Unless otherwise indicated, the terms “first,” “second,” etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

As used herein, a system, apparatus, structure, article, element, component, or hardware “configured to” perform a specified function is indeed capable of performing the specified function without any alteration, rather than merely having potential to perform the specified function after further modification. In other words, the system, apparatus, structure, article, element, component, or hardware “configured to” perform a specified function is specifically selected, created, implemented, utilized, programmed, and/or designed for the purpose of performing the specified function. As used herein, “configured to” denotes existing characteristics of a system, apparatus, structure, article, element, component, or hardware which enable the system, apparatus, structure, article, element, component, or hardware to perform the specified function without further modification. For purposes of this disclosure, a system, apparatus, structure, article, element, component, or hardware described as being “configured to” perform a particular function may additionally or alternatively be described as being “adapted to” and/or as being “operative to” perform that function.

The schematic flow chart diagrams included herein are generally set forth as logical flow chart diagrams. As such, the depicted order and labeled steps are indicative of one example of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

The present subject matter may be embodied in other specific forms without departing from its spirit or essential characteristics. The described examples are to be considered in all respects only as illustrative and not restrictive. All changes which come within the meaning and range of equivalency of the examples herein are to be embraced within their scope.

What is claimed is:

1. A method of mapping predicted aircraft exhaust plumes within a simulated airport environment, the method comprising:
generating an exhaust plume model for a simulated aircraft in a grounded position within the simulated airport environment, wherein the exhaust plume model is generated in response to predicted dynamic exhaust plume data for the simulated aircraft;
generating an airport feature map for the simulated airport environment, the airport feature map comprising a digital model of the simulated airport environment;
superimposing the exhaust plume model for the simulated aircraft in the grounded position onto the airport feature map to display a predicted exhaust plume on a computer display; and
analyzing the predicted exhaust plume to predict exhaust plume hazard zones within the simulated airport environment.

2. The method of claim 1, wherein the exhaust plume model is further generated in response to static exhaust plume data for the simulated aircraft.

3. The method of claim 1, wherein the airport feature map comprises non-movable features, configured to be fixed relative to a ground surface of the simulated airport environment, and movable features, configured to be movable relative to the ground surface of the simulated airport environment.

4. The method of claim 1, wherein the exhaust plume model for the simulated aircraft in the grounded position comprises a thrust level of at least one engine of the simulated aircraft.

5. The method of claim 4, wherein the thrust level of the at least one engine of the simulated aircraft is between ground idle thrust and maximum takeoff thrust of the simulated aircraft.

6. The method of claim 1, wherein:
the simulated aircraft is movable about a ground surface of the simulated airport environment;
the step of generating the exhaust plume model for the simulated aircraft further comprises generating the exhaust plume model for the simulated aircraft at a plurality of grounded positions within the simulated airport environment; and
the step of superimposing the exhaust plume model for the simulated aircraft further comprises superimposing the exhaust plume model for the simulated aircraft at each one of the plurality of grounded positions onto the airport feature map to display the predicted exhaust plume at each one of the plurality of grounded positions within the simulated airport environment on the computer display.

7. The method of claim 6, further comprising:
analyzing the predicted exhaust plume at each one of the plurality of grounded positions to predict exhaust plume hazard zones within the simulated airport environment; and
mapping a predicted path along the ground surface of the simulated airport environment wherein:
the predicted path comprises at least one of the plurality of grounded positions; and
the simulated aircraft is configured to move along the predicted path while maintaining the predicted exhaust plume out of the predicted exhaust plume hazard zones.

8. The method of claim 1, wherein generating the exhaust plume model for the simulated aircraft at the grounded position within the simulated airport environment comprises receiving at least one of:
information defining a headwind at the grounded position;
information defining a tailwind at the grounded position;
information defining a crosswind at the grounded position;
information defining an ambient temperature at the grounded position;
information defining a thrust level of the aircraft at the grounded position;
information defining aircraft engine configuration data of the simulated aircraft; and
information defining aircraft geometry and weight data of the simulated aircraft.

9. The method of claim 1, further comprising:
generating an exhaust plume model for a secondary simulated aircraft at a secondary grounded position within the simulated airport environment, wherein the exhaust plume model is generated in response to predicted dynamic exhaust plume data for the simulated secondary aircraft;
superimposing the exhaust plume model for the simulated secondary aircraft at the secondary grounded position onto the airport feature map to display a predicted secondary exhaust plume within the simulated airport environment on the computer display; and
analyzing the exhaust plume model for the simulated aircraft and the exhaust plume model for the simulated secondary aircraft to determine if the exhaust plume model of the simulated aircraft merges with the exhaust plume model of the simulated secondary aircraft.

10. The method of claim 9, further comprising:
analyzing the predicted exhaust plume and the predicted secondary exhaust plume to predict exhaust plume hazard zones within the simulated airport environment.

11. A system for mapping predicted aircraft exhaust plumes, the system comprising:
an aircraft in a grounded position within an airport environment;
a processor communicatively coupled with the aircraft; and
non-transitory computer readable storage media storing code, the code being executable by the processor to perform operations comprising:
generating an exhaust plume model for a simulated aircraft in a plurality of grounded position within a simulated airport environment, wherein:
the simulated aircraft is configured to simulate movement of the aircraft; and
the exhaust plume model is generated in response to predicted dynamic exhaust plume data for the simulated aircraft;
generating an airport feature map for the simulated airport environment, the airport feature map comprising a digital model of the simulated airport environment;
superimposing the exhaust plume model for the simulated aircraft at each one of the plurality of grounded positions onto the airport feature map to display a predicted exhaust plume at each one of the plurality of grounded positions on a computer display;
analyzing the predicted exhaust plume at each one of the plurality of grounded positions to predict exhaust plume hazard zones within the simulated airport environment; and
mapping a predicted path along the ground surface of the simulated airport environment wherein:
the predicted path comprises at least one of the plurality of grounded positions; and
the simulated aircraft is configured to move along the predicted path while maintaining the predicted exhaust plume out of the predict exhaust plume hazard zones,
wherein the aircraft is configured to move along a path in response to the predicted path within the airport environment.

12. The system of claim 11, wherein the exhaust plume model is further generated in response to static exhaust plume data for the simulated aircraft.

13. The system of claim 11, wherein processor is remote from the aircraft.

14. The system of claim 11, wherein the processor is onboard the aircraft.

15. The system of claim 11, wherein the predicted path is mapped in real-time as the aircraft is moved along the path in response to the predicted path within the airport environment.

16. The system of claim 11, wherein the step of generating the exhaust plume model for the simulated aircraft at the plurality of grounded positions within the simulated airport environment comprises receiving at least one of:
information defining a headwind at the grounded position;
information defining a tailwind at the grounded position;
information defining a crosswind at the grounded position;
information defining an ambient temperature at the grounded position;
information defining a thrust level of the aircraft at the grounded position;
information defining aircraft engine configuration data of the simulated aircraft; and
information defining aircraft geometry and weight data of the simulated aircraft.

17. A program product for mapping predicted aircraft exhaust plumes within a simulated airport environment comprising:
a non-transitory computer readable storage medium storing code, the code being configured to be executable by a processor to perform operations comprising:
generating an exhaust plume model for a simulated aircraft in a grounded position within the simulated airport environment, wherein the exhaust plume model is generated in response to predicted dynamic exhaust plume data for the simulated aircraft;
generating an airport feature map for the simulated airport environment, the airport feature map comprising a digital model of the simulated airport environment;
superimposing the exhaust plume model for the simulated aircraft in the grounded position onto the airport feature map to display a predicted exhaust plume on a computer display; and
analyzing the predicted exhaust plume to predict exhaust plume hazard zones.

18. The program product of claim 17, wherein the exhaust plume model is further generated in response to static exhaust plume data for the simulated aircraft.

19. The program product of claim 17, wherein the airport feature map comprises non-movable features, configured to be fixed relative to a ground surface of the simulated airport environment, and movable features, configured to be movable relative to the ground surface of the simulated airport environment.

20. The program product of claim 17, wherein the code is further configured to:
generate the exhaust plume model for the simulated aircraft at a plurality of grounded positions within the simulated airport environment; and
superimpose the exhaust plume model for the simulated aircraft for the plurality of grounded positions onto the airport feature map to display the predicted exhaust plume at each one of the plurality of grounded positions within the simulated airport environment on the computer display.
